(19) United States
(12) Patent Application Publication
(10) Pub. No.: US 2008/0037324 A1
(43) Pub. Date: Feb. 14, 2008

(54) Electrical thin film memory

(76) Inventors: Geoffrey Wen-Tai Shuy, Ma On Shan (HK); Raymond Ping Yiu Chiu, Kowloon Tong (HK)

Correspondence Address: FISH & RICHARDSON PC, P.O. BOX 1022, MINNEAPOLIS, MN, 55440-1022, US

(21) Appl. No.: 11/503,671

(22) Filed: Aug. 14, 2006

(51) Int. Cl. G11C 16/04

(52) U.S. Cl. 365/185.05

(57) ABSTRACT

A memory device includes a layer of material structure and a plurality of memory cells each formed using a corresponding different portion of the layer. Each memory cell is constructed and designed to change a material property of the corresponding portion of the layer upon application of an electrical write signal. The memory device includes circuitry for outputting a signal indicating presence or absence of a change of the material property in the memory cells.

### BACKGROUND

This invention relates to memory devices that make use of thin films that are accessed electrically.

Non-volatile memory devices are useful in storing-information, such as program code and data for computers and other electronic devices. An example of a non-volatile memory device is a flash memory device that includes an array of addressable memory cells. Each cell includes a floating gate metal oxide semiconductor (MOS) transistor, in which an electrically isolated floating gate is used to store charges. Flash memory devices have different types of architectures, such as NOR flash or NAND flash, that are suitable for different applications. In general, conventional NOR flash memory has longer write and erase times, but has a full address interface that allows random access to any location in the memory. NOR flash memory can be used for storage of program code that is updated infrequently and accessed randomly, such as a computer's basic input/output system (BIOS) or the firmware of set-top boxes. Conventional NAND flash memory generally has faster erase and write times, but the input/output interface is more suitable for sequential access to data rather than random access. NAND flash can be used for mass-storage devices such as various types of memory cards.

In some NOR flash memory devices, a ‘1’ bit can be written to a memory cell by injecting charges to the floating gate (for example, by channel hot-electron injection) to change an electrical state (i.e., accumulated charge) in the cell, which modifies a threshold voltage of the transistor. The ‘1’ bit can be erased by removing the electrons from the floating gate, for example, by Fowler-Nordheim tunneling. When a preset voltage is applied to a control gate, depending on whether charges are stored in the floating gate, the threshold voltage of the transistor will be different, so the electric current flowing through the transistor will also be different. A data bit can be read from the memory cell by applying a preset voltage to the control gate, and detecting the amount of electric current flowing through the transistor.

### SUMMARY

In a general aspect, information is recorded in a non-volatile electrical memory through a change of one or more material properties of a recordable layer. The recordable layer may include one or more thin layers of materials. Electrical circuitry, such as electrical conductors, are arranged such that at different locations of the layer the circuitry can (1) induce a current through the layer thereby changing material and electrical properties at that location and/or (2) sense electrical properties, such as resistance or capacitance, at that location.

In another general aspect, information is recorded in a non-volatile electrical memory by generating contrast between memory cells having diode-like current-voltage characteristics and memory cells having ohmic junction-like characteristics using one or more thin layers of organic or/and inorganic material.

In another general aspect, information is recorded in a non-volatile electrical memory by generating contrast in resistance using one or more thin layers of organic and/or inorganic material.

In another general aspect, information is recorded in a non-volatile electrical memory by generating contrast in capacitance using one or more thin layers of organic or/and inorganic material.

In another general aspect, information is recorded in a non-volatile electrical memory by generating contrast between resistive and capacitive, such as converting a material having a high resistivity (which is similar to a dielectric) to a material having lower resistivity (which is similar to a resistor), or vice versa, using one or more thin layers of inorganic and/or organic material.

In another general aspect, a memory device includes a layer of material, and a plurality of memory cells each formed using a corresponding different portion of the layer, wherein each memory cell is constructed and designed to change a material property of the corresponding portion of the layer upon application of an electrical write signal. The memory device includes circuitry for outputting a signal indicating presence or absence of a change of the material property in the memory cells.

Implementations of the memory device may include one or more of the following features. For each of at least some of the memory cells, prior to application of the write pulse, a Schottky barrier forms at an interface between the layer of material and a metal electrode or a metal layer, and after inscription, the interface becomes an ohmic junction. For each of at least some of the memory cells, the memory cell has a diode-like current-voltage characteristic before inscription, and has a resistor-like current-voltage characteristic after inscription. For each of the memory cells, the change in the material property of the layer is associated with a change in an electrical property of the layer. The electrical property includes a resistivity of the layer. In some examples, the resistivity decreases after application of the write signal. In some examples, the resistivity increases after application of the write signal. In some examples, the electrical property includes presence of a Schottky barrier. The electrical property includes a dielectric constant of the layer. In some examples, the dielectric constant decreases after application of the write signal. In some examples, the dielectric constant increases after application of the write signal. The memory device includes electrodes for transmitting the write signal. In some examples, at least one of the memory cells includes a layer that combines with a portion of the electrodes upon application of the write signal. At least one of the memory cells includes a first layer and a second layer that combine upon application of the write signal. The write signal includes a voltage pulse. In some examples, the memory device includes electrodes for sending the read and write signals to each memory cell, in which the electrodes do not interact with the layer of material upon application of the write signal to the memory cells.

In another general aspect, a memory device includes a plurality of memory cells, each memory cell constructed and designed to change a material property of a layer of material associated with the memory cell upon application of a write signal, and word lines and bit lines to select one or more memory cells. The memory device includes a controller to apply write signals to at least some of memory cells to change the material property of the layer of material associated with the at least some of the memory cells, and to apply read signals to at least some of memory cells to detect the material property at the at least some memory cells.

In another general aspect, a memory device includes a recording layer including a recordable stack of one or more material layers, at least one of the material layers having a thickness less than 50 nm, the recordable stack having a top surface and a bottom surface, and circuitry disposed on the top and the bottom surfaces of the recordable stack. The circuitry is configured to, at any of a plurality of selectable locations on the recordable stack, (a) apply an electrical signal across the stack at the selected location causing a change of a material property at that location, and/or (b) sense the material property of the recordable stack at that location.

Implementations of the memory device may include one or more of the following features. The circuitry includes a plurality of electrical conductors disposed on top and bottom surfaces of the recordable stack intersecting at the selectable locations. In some examples, at least one of the material layers is less than 25 nm thick. In some examples, at least one of the material layers is less than 10 nm thick. In some examples, at least one of the material layers is less three times a Debye length of the material in that layer. The stack of material layers includes a first layer and a second adjacent layer, the materials of the first and second layers being selected from a group consisting of: semiconductor/semiconductor, semiconductor/metal, semiconductor/metal oxide, and non-metal/metal. The electrical signal causes at least one of a chemical reaction between the layers, mixing of the layers, and diffusion of material between the layers, at that location. The electrical signal causes an endothermic chemical reaction between the layers. The memory device is non-volatile. The memory device is a write-once device.

In another general aspect, a method of accessing a memory device that includes a recordable layer and a plurality of memory cells each formed using a corresponding different portion of the recordable layer, the method including applying a write pulse to a memory cell to change a material property of the corresponding portion of the recordable layer of the memory cell to generate a contrast in the material property between the memory cell that has been applied the write pulse and other memory cells that have not been applied write pulses.

Implementations of the method may include one or more of the following features. The method includes applying a read pulse to a memory cell to probe the material property of the recordable layer of the memory cell, and reading a read signal representative of the material property at the memory cell. Changing a material property of the corresponding portion of the recordable layer includes changing the current-voltage characteristics of the recordable layer from diode-like characteristics before inscription to resistor-like characteristics after inscription. Changing a material property of the corresponding portion of the recordable layer includes changing a resistivity of the recordable layer. Changing a material property of the corresponding portion of the recordable layer includes changing a dielectric constant of the recordable layer. Changing a material property of the corresponding portion of the recordable layer includes causing at least one of a chemical reaction between the sub-layers of the recordable layer, mixing of the sub-layers, and diffusion of material between the sub-layers. Changing a material property of the corresponding portion of the recordable layer includes causing an endothermic chemical reaction between sub-layers of the recordable layer. Applying a write pulse includes applying a voltage pulse.

In another general aspect, a method includes fabricating a recordable layer and fabricating a plurality of memory cells each formed using a corresponding different portion of the recordable layer, wherein each memory cell is constructed and designed to change a material property of the corresponding portion of the recordable layer upon application of an electrical write signal. The method includes fabricating write circuitry for applying write signals to the memory cells, and fabricating read circuitry for outputting signals from the memory cells providing information about the material property of the recordable layer in the memory cells.

Implementations of the method may include one or more of the following features. Fabricating the recordable layer includes depositing two or more layers of materials on a substrate, in which at least one of the layers has a thickness less than 50 nm. Depositing two or more layers of materials includes depositing a layer of islands of material. Depositing two or more layers of materials includes depositing materials that interact in an endothermic reaction upon application of a write signal. Fabricating the plurality of memory cells includes using a 1-poly, 2-metal semiconductor process to fabricate the memory cells.

Aspects can have one or more of the following advantages. An advantage of using electrical thin film memory is that only a small amount of power is needed to write data to the memory. Another advantage is that an electrical thin film memory device can have a higher density of memory cells, hence a higher storage capacity than a flash memory device of the same physical size. Another advantage is that fabrication of the electrical thin film memory uses less material, and also can use a simpler fabrication process, as compared to flash memory. Another advantage of the electrical thin film memory is that data is written in the memory based on material change, and so the data will be less susceptible to electrical magnetic interference.

Other features and advantages of the invention are apparent from the following description, and from the claims.

### DESCRIPTION OF DRAWINGS

FIG. 1A is a perspective view of an electrical thin film memory device.

FIG. 1B is a side view of the memory device.

FIG. 1C is a top view of the memory device.

FIGS. 2 and 3 are graphs depicting the change of electrical characteristics before and after data inscription.

FIG. 4 is a chip.

FIG. 5 is a cross sectional view of the chip of FIG. 4 that includes a memory device.

FIGS. 6A-6F are layouts of the memory device of FIG. 5.

FIGS. 7A and 7B are cross sectional views of a memory device having two thin layers.

FIGS. 8A and 8B are cross sectional views of a memory device having three thin layers.

FIG. 9 is a cross sectional diagram of a memory device having multiple recordable layers.

FIG. 10 is a memory device that includes a memory controller and memory arrays.

FIG. 11 is the memory controller of FIG. 10.

FIG. 12 is a microcontroller that includes an electrical thin film memory device.

FIGS. 13A to 13C are graphs showing curves representing the current-voltage characteristics of an electrical thin film memory before and after inscription.

FIG. 13D is a schematic diagram representing an electrical thin film memory.

FIGS. 14A to 14C are graphs showing curves representing the current-voltage characteristics of an electrical thin film memory before and after inscription.

### DESCRIPTION

### 1. Overview

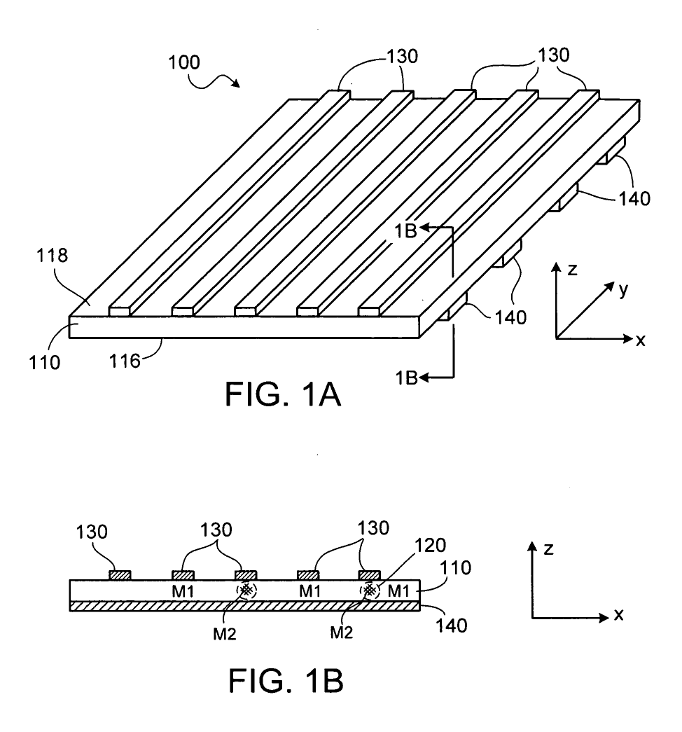

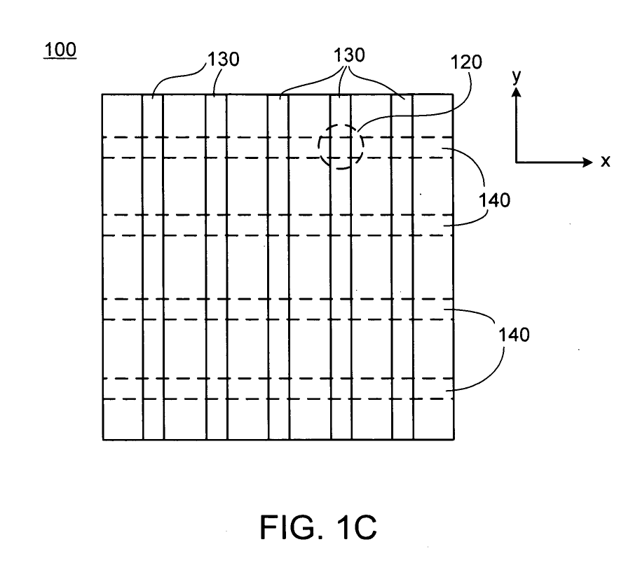

FIGS. 1A, 1B, and 1C show a perspective view, a side view, and a top view, respectively, of a portion of an electrical thin film memory device 100. The memory device 100 includes a recordable layer 110. A material property of the layer is modified upon application of an energy, thereby “writing” a mark to the layer. A material property of the layer (such as resistivity and/or permittivity (dielectric constant)) can be later detected using electrical methods (such as by applying an electrical read signal). Information is recorded in the memory device 100 based on contrast in the material property that can be detected, thereby “reading” from the layer to determine if a mark was previously written. For example, contrast in resistivity or permittivity between two regions of the recordable layer 110 can be detected by measuring a difference in resistances or capacitances, respectively, of the two regions. By using access circuitry that allows selective access to individual locations of the recordable layer 110, the memory device 100 can have multiple memory locations that can be individually modified and detected (i.e., written and read).

In this description, a change in a material property of a layer includes changes to the type (or types), density (or densities), or arrangement(s) of atoms or molecules in the layer. A change in material property of a layer may be associated with a change in one or more electrical properties (such as resistivity, permittivity, and junction characteristics such as a Schottky barrier or an ohmic junction) of the layer. A change in material property does not mean a change merely in the amount of electric charges accumulated at particular locations, such as accumulating charges in a capacitor or a floating gate.

In some examples, the access circuitry includes word lines 140 that are positioned on one side 116 of the recordable layer 110 and extend along an x-direction. Parallel word lines 140 are spaced apart along a y-direction. Bit lines 130 are positioned on another side 118 of the recordable layer 110 and extend along the y-direction. Parallel bit lines 130 are spaced apart along the x-direction. At each intersection of a word line 140 and a bit line 130 is a memory cell 120 that can be individually addressed. A mark is recorded in the memory cell 120 by applying a write pulse through a selected pair of a word line and a bit line, thereby changing a material property of a portion of the recordable layer 110 at the memory cell 120.

The memory cells 120 do not necessarily have distinct boundaries. The recordable layer 110 may be one or more continuous layers of materials, so the term “memory cell” is used in general to include a portion of the recordable layer 110 that can be individually accessed, such as by a selected pair of word and bit lines. A memory cell may include electrodes that are connected to the word and bit lines, and may include other components.

In versions of the approach in which the recordable layer 110 is a continuous layer and conductive word and bit lines are applied directly to the recordable layer 110, it is important that the recordable layer 110 is not entirely conductive in its unwritten (“virgin”) state, otherwise different memory cells may essentially be short-circuited. Thus, the recordable layer 110 is initially a dielectric or a resistive material, in which only localized regions have different resistivity and permittivity after applying the write pulse.

Energy can be applied to the layer of memory cell, for example, by applying a write pulse having a power level and/or duration sufficient to cause the modification in material property in the recordable layer 110. The write pulse may include a single pulse, or a series of sub-pulses (or other suitable voltage or current driving signal). As shown in FIG. 1B, when a write pulse is applied to a memory cell 120, the write pulse may induce an electric current to flow through the memory cell 120 and generate thermal energy, which causes the modification of material property in the recordable layer 110, for example, by causing a chemical reaction in the cell, or causing different materials to intermix. The material change may be irreversible in that other signals cannot be applied to reverse the modification of the material property. Examples of the material properties that may change upon application of the write pulse include resistivity and permittivity, and junction characteristics such as a Schottky barrier or an ohmic junction within the layer.

In this description, the term “before inscription” or “before writing” refers to a condition before a write pulse has been applied so that the recordable layer 110 maintains its “virgin” material and electrical properties. The term “after inscription” or “after writing” refers to a condition after the write pulse has been applied so that a material change occurs in the recordable layer 110, resulting in a change in a material property (as well as an electrical property). The term “recorded mark” refers to the portion of the recordable layer 110 in which material change has occurred.

### 2. Various Types of Memory Cells

The recordable layer can be composed of various materials. Depending on the selection of material for the recordable layer 110, the memory cell can be made, for example, (1) to have characteristics similar to a diode before inscription and become resistive after inscription, (2) resistive before and after inscription with different levels of resistance, (3) capacitive before and after inscription with different levels of capacitance, (4) primarily resistive before inscription and primarily capacitive after inscription, (5) primarily capacitive before inscription and primarily resistive after inscription, and (6) resistive before inscription and become diode like after inscription.

### 2.1 Diode-Like to Resistive Memory Cells

Memory cells 120 that have diode-like current-voltage characteristics before inscription and resistor-like current-voltage characteristics after inscription can be designed by selecting the materials for the recordable layer 110, the bit line 130, and the word line 140 such that, before inscription, a potential barrier exists in the memory cell, and after inscription, the potential barrier decreases or diminishes. In some examples, the potential barrier is generated by selecting a particular semiconductor or insulator material for the recordable layer 110 and particular types of metal for the bit and word lines 130 and 140, such that a Schottky barrier is formed at at least one of the interfaces between the semiconductor material and the metal lines.

The diode-like current-voltage characteristics can include, for example, a non-linear current-voltage relationship, where the slope of the current-voltage curve is small when the voltage is below a threshold voltage, and the slope increases significantly when the voltage is larger than the threshold voltage. The resistor-like current-voltage characteristics can include, for example, a current-voltage relationship that is substantially linear.

The semiconductor (or insulator) and metal materials can be selected such that, before inscription, there is a Schottky barrier at the interface between the recordable layer 110 and the bit line 130 (or alternatively the word line 140), and an ohmic contact at the interface between the recordable layer 110 and the word line 140 (or alternatively the bit line 130). The semiconductor (or insulator) and metal materials can also be selected such that, before inscription, Schottky barriers are formed at both interfaces between the recordable layer 110 and the bit line 130 and between the recordable layer 110 and the word line 140.

Due to the Schottky barrier(s), the memory cell 120 does not conduct current (except for a small leakage current) when a small voltage is applied to bias the memory cell 120. Current starts to flow when the forward-bias voltage increases above a threshold voltage V_{T}. After inscription, due to thermal energy induced by the current during inscription, a portion of the metal material fuses with the semiconductor material such that the interface between the recordable layer 110 and the metal bit line 130, and the interface between the recordable layer 110 and the metal word line 140, behave similar to ohmic junctions. Thus, after inscription, the memory cell 120 behaves like a resistor.

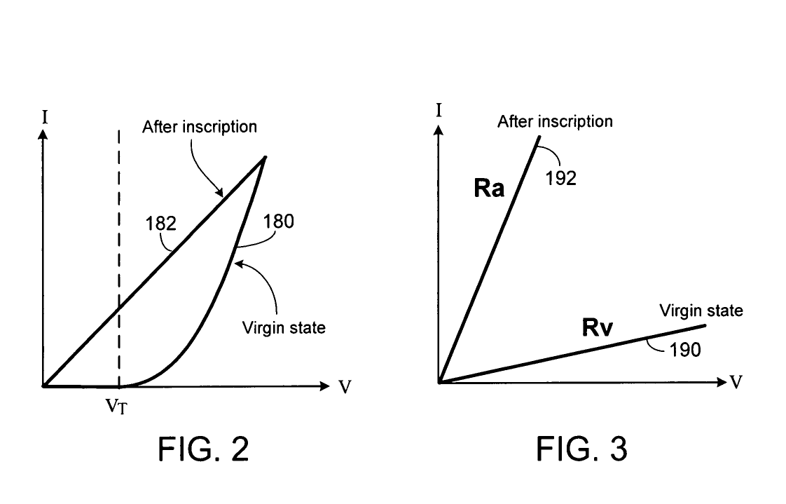

FIG. 2 shows I-V curves 180 and 182 that represent the current versus voltage characteristics of the memory cell 120 before and after inscription, respectively. As indicated by the I-V curve 180, before inscription, the memory cell 120 has characteristics similar to a diode. When the forward bias voltage V is less than the threshold voltage V_{T}, the current I is negligible, or equal to a small leakage current that does not increase proportionally with respect to the applied voltage V. As indicated by the I-V curve 182, after inscription, the memory cell 120 behaves like a resistor, in which the leakage current is proportional to the applied voltage V, even for small voltages. By applying a read pulse having a voltage V between 0 volt and V_{T} to the memory cell 120, and sensing the current I that flows through the memory cell, one can determine whether the memory cell has been inscribed. For example, a memory cell that has been inscribed may represent a data bit of “1,” and a memory cell still in its virgin state may represent a data bit of “0.”

The write pulse may have a voltage level of, for example, 3 volts, and the read pulse may have a voltage level of, for example, 50 to 700 mV. Information can be carried in the memory device 100 by generating contrasts in the leakage current among different memory cells 120. The amount of contrast in current can be represented by I1/I2, where I1 is the leakage current before inscription and I2 is the leakage current after inscription. In some examples, the amount of contrast in leakage current can be greater than 10.

When designing the memory cell 120, the type of semiconductor material used for the recordable layer 110, the doping level (if doping is used) of the semiconductor material, and the type(s) of metal used for the bit line 130 and word line 140, are selected such that the memory cell 120 has a particular diode-like characteristic before inscription and a particular resistor-like characteristic after inscription, thereby producing a desired contrast before and after inscription.

### 2.2 Resistive Memory Cells

In some examples, the memory cells 120 are primarily resistive before and after applying a write pulse. By saying that the memory cell 120 is resistive, it is meant that either before or after inscription, the memory cell 120 behaves like a resistor and has a resistance such that when a read pulse is applied to the memory cell 120, a detectable DC current flows through the memory cell 120.

The recordable layer 110 can include dielectric or semiconductor materials. In some examples where the recordable layer 110 is a semiconductor material, the type of semiconductor material used, the doping level (if any) of the semiconductor material, and the type(s) of metal used for the bit line 130 and word line 140, are selected such that ohmic contacts are formed at the interface between the recordable layer 110 and the bit line 130, and at the interface between the recordable layer 110 and the word line 140. This way, the memory cell 120 have resistor-like current-voltage characteristics both before and after inscription.

In some examples, the resistance at a memory cell 120 decreases after inscription. This can be thought of as an “anti-fuse” in that it has the opposite behavior of a fuse, which changes from a lower resistivity state (normal fuse) to a higher resistivity state (blown fuse). For example, the recordable layer 110 can have a thin layer of metal sandwiched between two thin layers of semiconductor materials. Upon applying a write pulse, the metal diffuses to adjacent semiconductor layers, causing the overall resistance of the memory cell to decrease.

FIG. 3 shows I-V curves 190 and 192 that represent the current versus voltage characteristics of a resistive memory cell 120 before and after inscription, respectively, in which the resistance of the memory cell decreases after inscription. By applying a read pulse having a voltage V and sensing the current I that flows through the memory cell, one can determine whether the memory cell has been inscribed.

The write pulse may have a voltage level of, for example, 3 volts, and the read pulse may have a voltage level of, for example, 50 to 700 mV. Information can be carried in the memory device 100 by generating contrasts in resistivity among different memory cells 120. The amount of contrast in resistance can be represented by R1/R2, where R1 is the resistance before inscription and R2 is the resistance after inscription. In some examples, the amount of contrast in resistance can be greater than 10.

In some examples, the resistance at a memory cell 120 may increase after inscription. In this case, the amount of contrast in resistance can be represented by R2/R1, where R1 is the resistance before inscription and R2 is the resistance after inscription.

### 2.3 Capacitive Memory Cells

In some examples, the memory cell 120 is primarily capacitive before and after applying a write pulse. The capacitance at the memory cell 120 may increases after inscription. By saying that the memory cell 120 is primarily capacitive, it is meant that the recordable layer 110 at the memory cell is similar to a dielectric, such that the memory cell 120 behaves like a capacitor. In some examples, the capacitance at the memory location 120 decreases after inscription. The increase or decrease in capacitance may be caused by an increase or decrease in the permittivity of the recordable layer 110 at the memory cell 120. Information can be carried in the memory device 100 by generating contrasts in capacitances among different memory cells 120.

The capacitance of a capacitor can be measured using a number of ways. For example, a constant current is driven through the capacitor for a specified period of time, and the voltage level across the capacitor is measured. The amount of charge (Q) stored at the capacitor is equal to the current (I) multiplied by the charging time (T). The value Q is also equal to the capacitance, C, multiplied by the voltage (V) across the capacitor. Because Q=I*T=C*V, the capacitance can be determined by C=I*T/V.

As another example, electric currents I are sent through a reference capacitor (having a known capacitance C1) and another capacitor having an unknown capacitance (C2) for a specified period of time, and voltages V1 and V2 across the reference capacitor and the other capacitor, respectively, are measured. Because the charges stored on the two capacitors will be the same Q=I*T=C1*V1=C2*V2, the capacitance C2 can be determined using C2=C1*V1/V2.

As another example, when a voltage V1 is applied to the memory cell 120, the voltage difference across the memory cell 120 rises from 0 to V1, and the speed of the current increase depends on the capacitance of the memory cell 120. At steady state, no DC current (or a negligible amount of DC current) flows through the memory cell 120. Another way of sensing a capacitor is to send an AC signal having a specific frequency through the memory cell 120 to detect the change in AC impedance or resonance state. For example, the memory cell 120 can be designed so that there is resonance at the specific frequency before inscription, and the resonance deceases after inscription, or vise versa.

The amount of contrast in capacitance can be represented by C1/C2 or C2/C1, depending on whether the capacitance decreases or increases, respectively, in which C1 is the capacitance before inscription and C2 is the capacitance after inscription. In some examples the amount of contrast in capacitance can be greater than 10.

### 2.4 Memory Cells that Switch Between Resistive and Capacitive

In some examples, prior to inscription, the memory cell 120 is primarily capacitive, but after inscription, the memory cell 120 becomes primarily resistive. In this case, prior to inscription, the recordable layer 110 behaves like an insulator (for DC current), but after inscription, the recordable layer 110 behaves like a resistor and has a resistance that allows a detectable electric current to flow through the memory cell 110 upon application of a read pulse. This type of memory cells can be read out by either the change in leakage currents before and after inscription, or by the change in resonance state when an AC signal having a specific frequency is sent through the memory cell.

In some examples, prior to inscription, the memory cell 120 is resistive, but after inscription, the memory cell 120 becomes capacitive. In this case, prior to inscription, the recordable layer 110 has a resistance that allows a detectable electric current to flow through the memory cell 110 upon application of a read pulse, but after inscription, the recordable layer 110 becomes similar to a dielectric. This type of memory cells can also be read out by either the change in leakage currents before and after inscription, or by the change in resonance state when an AC signal having a specific frequency is sent through the memory cell.

The contrast in electrical property can be measured in the amount of contrast in capacitance (C1/C2 or C2/C1, in which C1 and C2 are the capacitances before and after inscription, respectively) or leakage current (I1/I2 or I2/I1, in which I1 and I2 are the leakage currents before and after inscription, respectively).

### 2.5 Diode-Like to Resistive Memory Cells

The materials for the memory cells 120 can also be selected such that the memory cells 120 have resistor-like current-voltage characteristics before inscription and diode-like current-voltage characteristics after inscription.

### 3. Mechanisms for Modifying the Material Property of the Recordable Layer

The recordable layer 110 can be a single layer of material, or have multiple layers of different materials. In some examples, the recordable layer 110 itself may undergo material change without interacting with the electrodes. For example, the layer 110 itself may undergo phase change, or the layer 110 may include two or more sub-layers that interact with each other. In some examples, the recordable layer 110 may interact with the electrodes that contact the layer, for example, as part of writing and/or reading circuitry. The materials of the electrodes may diffuse into the layer 110, the electrode and the material of layer 110 may form an alloy, or a chemical reaction may occur between the electrode material and the material of layer 110.

### 3.1 Recordable Layer Having One Thin Layer

In the example of FIGS. 1A and 1B, the recordable layer 110 is a single layer of material M1 that interacts with one or both of the electrodes 130 and 140 upon application of a write pulse. In this version of the memory device 100, the layer 110 has a thickness of less than the Debye length of M1, such as between 10 to 50 nm. The word and bit lines 140 and 130 can be made of, for example, aluminum.

Referring to FIG. 1B, when a write pulse is applied to a memory cell 120, a current flows from the bit line 130 to the word line 140 (or vice versa), and the electric field generated across the film can induce stress, sometimes causing “material break down.” The electric current dissipates thermal energy into the recordable layer that is proportional to I²R, where I represents the electric current and R represents the resistance of the thin film. In some examples, the layer 110 is made of silicon. The eutectics point of Si—Al is about 290° C. When the write pulse heats the silicon layer to above 290° C., the silicon layer fuses with the aluminum electrodes and forms an Al—Si eutectics material that has a material property different from Si. The material in the recordable layer 110 changes irreversibly from a material having a relatively higher resistance (e.g., pure silicon) to another material having a relatively lower resistance (e.g., an alloy of silicon and aluminum). Such memory cells using material change to record data is different from conventional memory cells that use storage of electric charges to record data.

Germanium or other semiconductor materials can also be used for the recordable layer 110.

Dissipating thermal energy in the recordable layer 110 increases the temperature of the recordable layer 110 and on the electrodes 130, 140. This causes a portion of the electrodes 130 and 140 to interact with the recordable layer 110 to form a material M2. As described in more detail in the next section, when the recordable layer 110 is thin, only a small amount of thermal energy is required to cause the materials in the electrodes 130 and 140 to interact with the recordable layer 110.

In general, the material M2 has an electrical property (for example, resistance or capacitance) that is different from the electric property of the layer of material M1. In some examples, the interaction between the electrodes 130 and 140 and the recordable layer 110 induced by the write pulse is endothermic and confined to a region in which the dissipated energy from the electric current is above a threshold volumetric power density (watts/m³) and volumetric energy density (J/m³) (that is, to have enough power level per unit volume for a sufficient duration of time). The memory cells associated with endothermic reactions can be packed denser than memory cells associated with exothermic reactions. If an exothermic reaction is induced in a memory cell by a write pulse, the size of region in the recordable layer 110 in which the exothermic reaction occurs is determined by how far the heat wavefront spreads before cooling off. Memory cells associated with exothermic reactions have to be spaced apart further to prevent interference between adjacent cells.

Using a 130 nm semiconductor fabrication process, where the word and bit lines can be made as small as 130 nm and are spaced apart at 130 nm, each memory cell 120 can have a dimension of 260 nm by 260 nm in the x-y plane. By comparison, in an NAND flash memory also fabricated using 130 nm technology, the average cell size would be 390 nm by 390 nm. That is, the spatial density of memory cells 120 of the electrical thin film memory device 100 can be higher than or comparable to that of flash memory devices.

When the inscription process results in an endothermic reaction, heat is generated by the energy dissipation from the write pulse, and therefore is controllable and more limited than in situations in which the write pulse triggers an exothermic reaction in the recordable layer. Also, because less heat is generated, there is less heat dissipation problems. This limited and controllable heat generation is useful, for example, when multiple inscription layers are stacked in a single memory device, as will be described later.

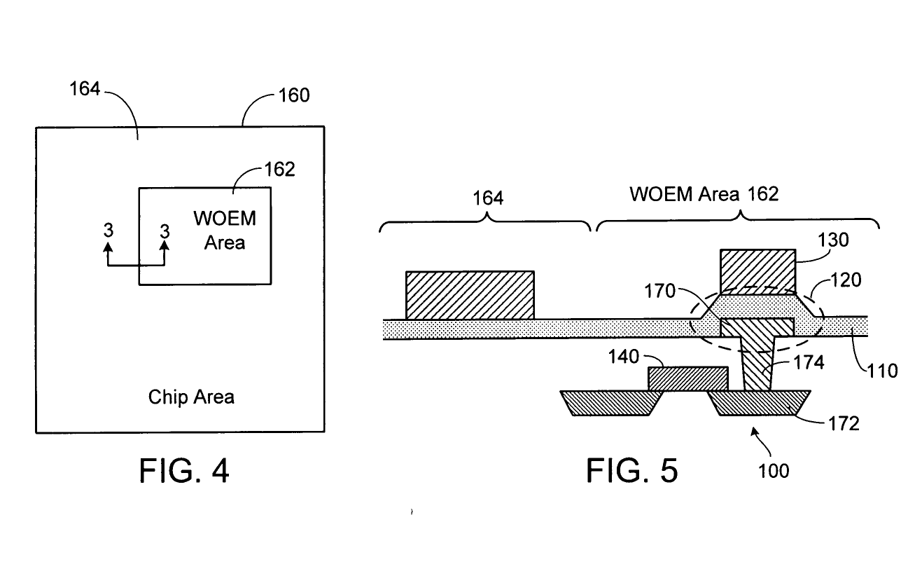

FIG. 4 shows an example of a chip 160 that includes an electrical write-once memory (EWOM) area 162 for fabricating the electrical thin film memory device 100. The device 100 includes word lines, bit lines, and the recordable layer, but does not necessarily include active devices, such as transistors. The active devices for selecting the word lines and bit lines are fabricated in an area 164 outside of the EWOM area 162.

The area 164 may include other circuitry, such as a central processing unit or a microcontroller. The chip 160, including the electrical thin film memory device 100 and other modules, can be fabricated using a process that is similar to the standard 1-poly, 2-metal semiconductor process, which is capable of fabricating devices having a poly-silicon layer, a first metal layer, a second metal layer, and a nitride layer. A photo mask is used to pattern each layer to achieve the desired geometry.

FIG. 5 shows a cross sectional diagram (not to scale) of a portion of the EWOM area 162 and a portion of the chip area 164 outside of the EWOM area 162. The EWOM area 162 includes an electrical thin-film memory device 100, in which a memory cell 120 is shown in the figure. The memory cell 120 includes a portion of a recordable layer 110 that changes a material/electrical property after inscription. The recordable layer 110 can be a continuous layer that covers the entire chip 160, so that it is not necessary to use an additional photo mask to pattern the recordable layer 110.

The recordable layer 110 is sandwiched between a bit line 130 and a contact 170, which are fabricated using the second metal layer and the first metal layer, respectively, of the 1-poly, 2-metal process. A word line 140 is fabricated using the poly-silicon layer of the 1-poly, 2-metal process. A doped nitride region 172 provides an electrical path from the word line 140 to the contact 170.

The devices in the area 164 are also fabricated using the same 1-poly, 2-metal process used for fabricating the memory cells 120. In the area 164, the devices, such as transistors, can be fabricated above and/or below the recordable layer 110.

In this example, the recordable layer 110 is a semiconductor layer, such as a silicon or germanium layer. Before inscription, a Schottky barrier exists between the bit line 130 and the semiconductor layer 110, and between the semiconductor layer 110 and the contact 170. The memory cell 120 has current-voltage characteristics similar to a diode (see FIG. 2). When a read pulse having a voltage of, e.g., 50 mV is applied between the bit line and the word line, negligible current flows through the memory cell 120. When a write pulse of, e.g., 3 volts is applied between the word line 140 and bit line 130, portions of the bit line 130 and the contact 170 fuse (e.g., diffuse into) with the recordable layer 110, such that the interface between the recordable layer 110 and the bit line 130, and the interface between the recordable layer 110 and the contact 170, become ohmic contacts (thereby removing the Schottky barriers). The mixture of the metal and semiconductor materials behaves like a resistor having a resistance R. After inscription, when a read pulse having voltage of, e.g., 50 mV is applied between the bit line and the word line, a current I=V/R=50 mV/R flows through the memory cell 120 and can be detected by the sensing circuitry fabricated in the area 164 of the chip 160. The current-voltage characteristics before and after inscription are similar to those depicted in FIG. 2.

In some examples, the width of the bit line is 1300 nm, and the thickness of the recordable layer 110 is between about 5 nm to about 50 nm.

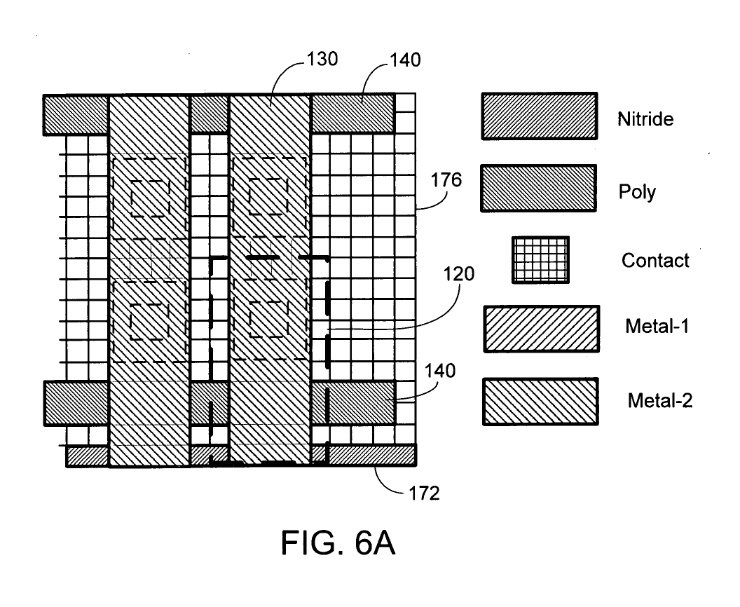

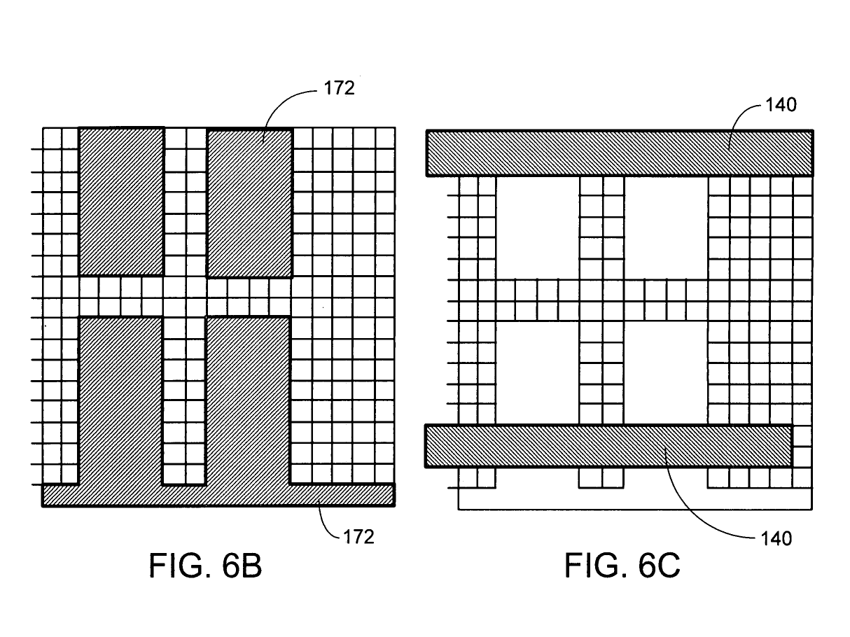

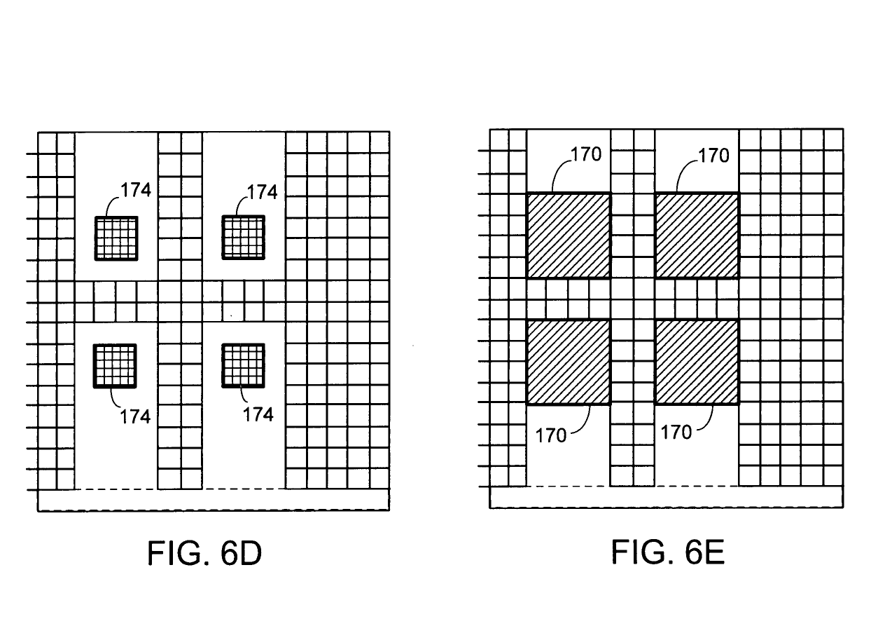

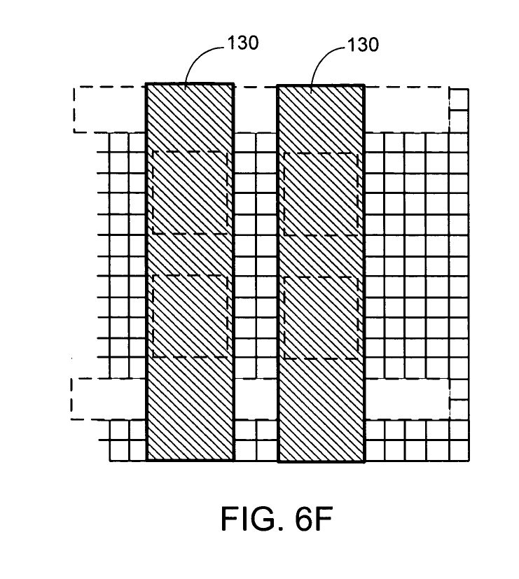

FIG. 6A shows a top view of a layout of an NOR type electrical thin film memory device 100 (with upper layer obscuring lower layers). The figure shows a grid reference 176 in which each small square represents an area of 1λ by 1λ, λ representing the wavelength of light used in the photolithography process to define the geometry of the layers. Each memory cell 120 (one of which is enclosed in thick dashed lines) occupies an area of 6 λ by 10 λ. This size is comparable to the size of a contact programmable NOR type ROM device. Each memory cell 120 can be accessed by a bit line 130 and a word line 140. FIG. 6A shows two complete memory cells (at the lower portion of the figure) and two partial memory cells (at the upper portion of the figure).

Also shown in FIG. 6A are the legends for the nitride, poly-silicon, contact, metal-1, and metal-2 layers. During fabrication of the device 100, in general, the nitride layer is formed first (deposited, etched, and doped), followed in sequence by the poly-silicon layer, the first metal layer, the recordable layer 110, and the second metal layer.

FIGS. 6B to 6F each shows the layout of a different layer of the memory device 100. FIG. 6B shows the layout of the nitride layer 172, a portion of which is doped to provide an electrical path between the poly-silicon word line 140 and the contact 170. FIG. 6C shows the layout of the poly-silicon word lines 140. FIG. 6D shows the layout of the lower portion 174 of the contact 170. FIG. 6E shows the layout of the upper portion of the contact 170, which is made from the first metal layer 170.

FIG. 6F shows the layout of the bit lines 140, which is fabricated from the second metal layer of the 1-poly, 2-metal process. The recordable layer 110 is positioned between the bit line 140 and the upper portion of the contact 170. The recordable layer 110 is deposited on the chip 160 before the second metal layer is deposited.

### 3.2 A Recordable Layer Having Two or More Thin Layers

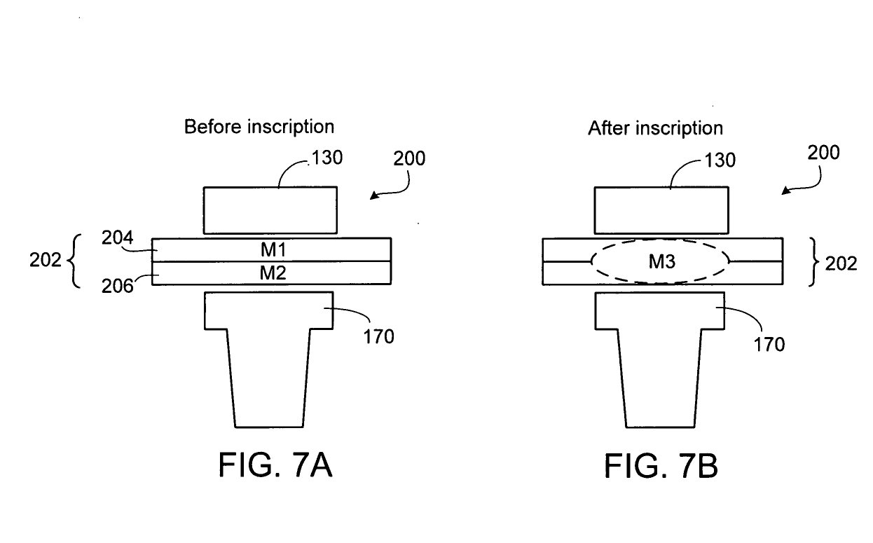

FIGS. 7A and 7B show examples of a memory cell of an electrical thin film memory device 200 before and after inscription, respectively. The device 200 is similar to the device 100 of FIG. 5, except that the recordable layer 202 of the device 200 has two layers 204 and 206 of different materials M1 and M2, respectively, that interact upon application of a write pulse. For example, the first layer 204 has a thickness of less than the Debye length of M1 (e.g., 10 nm), and the material M1 can be silicon. The second layer 206 has a thickness of less than the Debye length of M2 (e.g., 15 nm), and the material M2 can be germanium.

When a write pulse is applied to a memory cell of the device 200, the materials M1 and M2 combine (for example, in an endothermic reaction) to form a material M3. As described in more detail in the next section, when the layers 204 and 206 are thin, only a small amount of thermal energy is required to cause the materials M1 and M2 to combine.

In general, the material M3 has an electrical property (for example, resistance or capacitance) that is different from the electrical property of the layers of materials M1 and M2 considered together. In some examples, the reaction in the recordable layer 202 induced by the write pulse is an endothermic reaction and the recorded mark is generally confined to a region in which the dissipated energy from the electric current is above a threshold volumetric power density and volumetric energy density. The memory cells associated with endothermic reactions can be packed denser than memory cells associated with exothermic reactions. Similar to the electrical thin film memory device 100, when a 130 nm semiconductor fabrication process is used, each memory cell of the device 200 can have a dimension of 260 nm by 260 nm in the x-y plane. Because the reaction between the materials M1 and M2 can be an endothermic reaction, there is less heat dissipation problem, allowing multiple inscription layers to be stacked along the z-direction in a single memory device, as will be described later.

In FIG. 7A, the materials M1 and M2, and the materials for the bit line 130 and contact 170 can be selected so that the memory cell 200 behaves like any of the five types of memory cells described above. Namely, the memory cell 200 can change from diode-like to resistor-like, be resistive, capacitive, change from resistive to capacitive, or change from capacitive to resistive before and after inscription.

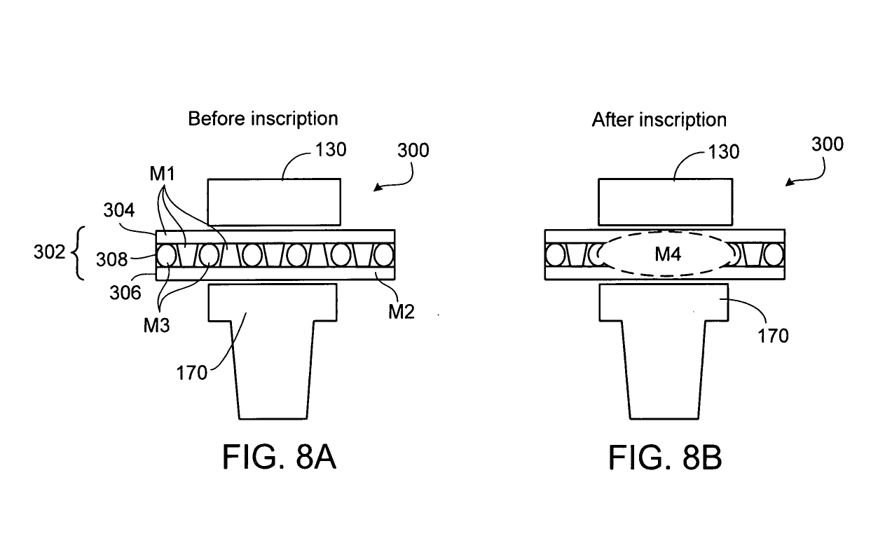

FIGS. 8A and 8B show examples of a memory cell of an electrical thin film memory device 300 before and after inscription, respectively. The device 300 is similar to the device 100 of FIG. 5, except that the recordable layer of the device 300 has a thin layer 308 of “islands” of material M3 sandwiched between two thin layers 304 and 306 of materials M1 and M2. In FIGS. 8A and 8B, the islands of material M3 are shown as small balls. In actual implementations, the islands of material M3 can have an irregular shape in the x-y plane. Upon application of a write pulse, the layers 304, 306, and 308 interact to form a material M4. Additional explanation of the islands of material is provided in section 6.2 below.

The following are some examples of materials and thicknesses of the layers of the device 300. The first layer 304 can have a thickness in the range of 2 nm to 20 nm, and the material M1 can be a semiconductor (e.g., silicon or germanium) or insulator. The second layer 306 can have a thickness in the range of 2 nm to 20 nm, and the material M2 can also be a semiconductor (e.g., silicon or germanium) or insulator. The materials M1 and M2 can be the same or different. The material M3 can be a metal, such as aluminum or aluminum alloy.

The layer 308 of islands of material M3 can have an effective thickness that is smaller than the thickness of a continuous layer. The effective thickness is explained in more detail in section 6.2 below. The diameters of the islands can be made smaller than the width of the bit line 130. For example, when 130 nm semiconductor fabrication process is used, the width of the bit line can be 130 nm, and the diameter of the islands can be made to be about 10 nm. Because each bit line covers several islands, the islands appear to the bit lines as a continuous layer having the effective thickness.

When a write pulse is applied to a memory cell of the device 300, the materials M1, M2, and M3 combine (for example, in an endothermic reaction) to form a material M4. As described in more detail in the next section, when the layers 304, 306, and 308 are thin, only a small amount of thermal energy is required to cause the materials M1, M2, and M3 to combine.

In FIG. 8A, the materials M1, M2, and M3, and the materials for the bit line 130 and contact 170 can be selected so that the memory cell 300 behaves like any of the five types of memory cells described above. Namely, the memory cell 300 can change from diode-like to resistor-like, be resistive, be capacitive, change from resistive to capacitive, or change from capacitive to resistive before and after inscription.

When M3 is a metal and M1 and M2 are semiconductors or insulators, after inscription, because the metal M3 diffuses into the layers 304 and 306, the resistance of the layer 302 decreases after inscription.

The reaction in the recordable layer 302 induced by the write pulse is an endothermic reaction and the recorded mark is generally confined to a region in which the absorbed energy from the electric current is above a threshold volumetric power density and volumetric energy density. The memory cells associated with endothermic reactions can be packed denser than memory cells associated with exothermic reactions. Similar to the electrical thin film memory device 100, when a 130 nm semiconductor fabrication process is used, each memory cell of the device 300 can have a dimension of 260 nm by 260 nm in the x-y plane. Because the reaction between the materials M1, M2, and M3 can be an endothermic reaction, there is less heat dissipation problem, allowing multiple inscription layers to be stacked in a single memory device, as will be described later.

In general, when designing a recordable layer 110 having two or three layers, the materials and thicknesses of the layers are selected so that the intermixing and reaction among the layers results in an intended contrast in resistance and/or capacitance before and after inscription.

The middle layer can also be a continuous layer, so that the recordable layer has three continuous layers that combine after inscription. The layers can include organic or inorganic materials. Inorganic materials are usually more stable than organic materials, and therefore a memory device 100 that uses inorganic materials in the recordable layer 110 may be more reliable than another memory device that uses organic materials.

In some examples, the recordable layer 110 includes a continuous layer of metal or semiconductor, having a thickness of about 15 nm, sandwiched between two layers of islands of material (each having an effective thickness of about 5 nm). The islands of material can be insulator or semiconductor. Both before and after inscription, the memory cell behaves like a resistor. The resistance of the memory cell decreases after inscription.

In some examples, a recordable layer having four or more thin sub-layers may be used. Increasing the number of layers may increase the contrast in electrical properties before and after inscription, or designed to achieve the desired contrast reliably, or to fit in with the integrated circuit system requirements.

### 3.3 Theory of Thin Layers

Without being limited by any theory presented herein, behavior of recordable layers having thin sub-layers may be at least partially understood according to the following. A parameter, referred to as the Debye length of a material, relates generally to the distance in the material to which the applied charges or fields have effect. The Debye lengths of materials of the recordable layer can be useful to predict or explain the behavior of the recordable layer.

The combination of materials M1 and M2 during inscription may be aided by a strong electric field created in the charges moved across the interface between M1 and M2, and the thinness of the recording layer relative to the Debye length of the materials in the recordable layer. That is, even without the addition of an external electric field (e.g., between conductors), the charge transfer creates a significant electric field.

The Debye length of a material, which relates generally to the thickness of the cloud of charge carriers in the material that shields an applied charge or electric field depends on the charge carrier density. When a charged particle is placed in a material, the charged particle will attract charge carriers having opposite polarity, so that a cloud of charge carriers will surround the charged particle. The cloud of charge carriers shields the electric field from the charged particle, and the higher the charge carrier density, the greater the shielding effect within a given distance. Due to shielding by the charged particles, the electric potential φ decays exponentially according the equation

φ=φ₀·exp(−|x|/λ_{D}),

where φ₀ is the electric potential at the charged particle, x is the distance from the charged particle, and λ_{D} is the Debye length, which can be represented by:

$${λ}_{D} = \frac{1}{e} \sqrt{\frac{K \cdot {T}_{e}}{4 π n}} \approx 6.9 \sqrt{\frac{T}{n}} cm ( T in °K . ) . \qquad ( Equ . 1 )$$

### See “Introduction to Plasma Physics,” by Francis Chen, Section 1.4: Debye Shielding, pages 8-11. The Debye length represents a measure of the shielding distance or thickness of the cloud of charge carriers.

When there are fluctuations in an electric field created by changes in a localized charge density in a material, the influences of the fluctuations are mostly felt by charge carriers located within a few Debye lengths. The charge density changes can be induced by, for example, charge carriers moving through interfaces, or charge density fluctuations induced by outside electromagnetic field or due to thermal effects.

When two materials having different electron energy levels (such as different highest unoccupied electron energy level, called conduction band, or HUMO, and lowest occupied electron energy level, called valance band, or LOMO) contact, charge separation will cause an electric field to be generated at the interface. The influence of the electric field is shielded or reduced by a sheath of charge carriers near the interface. When the two materials are thin layers, for example, the total thickness of the thin layers is less than the Debye length, there will be a strong electric field throughout the entirety of the two layers, which can be as strong as 100,000 V/cm. The strong electric field can assist the materials in the two layers to interact and combine upon an energy application (such as dissipated thermal energy induced by the write pulse). By comparison, when the layers are thick, the electric field in most of the cross-section of the layers is negligible and does not provide assistance in the interaction of the materials in the two layers.

The same principle can be applied to the interaction or combination of three or more thin layers of materials.

For semiconductors, n (in Equ. 1) is about 10¹⁷ to 10¹⁹, its square root is about 3×10⁸ to 3×10⁹, and T is about 300° K. at room temperature, so the Debye length is about 10 to 100 nm. For metals, n is about 10²¹ to 10²³, so the Debye length is about 1 to 10 nm. For example, the Debye length for aluminum is less than 1 nm at room temperature, and is about 2 nm at 700° K. The Debye length for Ge doped with impurities is about 30 nm to 80 nm at room temperature, depending on the concentration of impurities.

A feature of a recordable layer having thin layers is that the large electric field can assist endothermic reaction, which does not release heat during the reaction. Only a small area power density (watts/m²) is required to cause the combination of the two layers. The recorded mark is well defined—only the portion of the two layers in which the electric current passes so as to generate thermal energy above an absorbed threshold volumetric power density, and also above an absorbed threshold volumetric energy density (i.e., to have enough power level and enough duration time of high-power), will combine.

An advantage of using thin layers is that less energy may be required to cause the thin layers to combine. For a given write speed, the write pulse can have a lower voltage (for example, compared to the writing voltage of a flash memory). For a given write pulse having a specified voltage, a shorter duration of the write pulse can be used for writing to each memory cell, resulting in a faster writing speed. Another advantage of using thin layers is that less materials for the layers are required, thereby reducing the material costs and the processing costs of coating or depositing the layers. When expensive materials are used for the layers, such as gold or silver, the cost savings for manufacturing a large number of memory devices can be significant.

When there is a strong electric field, there is an electric potential across the interface, so a small amount of energy can cause the molecules to move across the interface (from a higher potential region to a lower potential region), causing materials from the two layers to intermix.

### 4. Selecting Materials

The materials and thicknesses of the layers can be selected based on information from a pre-established database. The database can be established by measuring the electrical properties of various thin layers or combinations of thin layers of various materials. The database can include information about the resistance and/or capacitance per unit area, and diode-like characteristics, of (1) a single layer of material at different thicknesses, and (2) various combinations of materials of varying thicknesses, before and after inscription. The materials and thicknesses of the layers are selected to achieve a desired contrast in resistance and/or capacitance before and after inscription.

Each memory cell includes at least two interfaces—an interface between a recordable layer (e.g., 110 in FIGS. 1A and 5, 202 in FIG. 7A, 302 in FIG. 8) and a bit line 130 (or an electrode that couples the recordable layer to the bit line), and an interface between the recordable layer and a word line 140 (or an electrode that connects to the word line). When the recordable layer includes one layer of material, the material can be either semiconductor or insulator. When the recordable layer includes two or more materials, there are additional interfaces in the recordable layer. If the recordable layer includes two layers of materials, each of the two layers of materials can be either semiconductor or insulator. If the recordable layer includes three or more layers of materials, the recordable layer can also include a metal in between semiconductor or insulator materials.

In the example of fabricating a memory device that switches from having resistor-like characteristic to having diode-line characteristic, the materials for the recordable layer, bit line, and word line (or electrodes that connect to the bit line or word line) can be selected such that, before inscription, there is a Schottky barrier at the interface between the recordable layer and the bit line (or alternatively the word line), and an ohmic contact at the interface between the recordable layer and the word line (or alternatively the bit line). The materials can also be selected such that, before inscription, Schottky barriers are formed at both interfaces between the recordable layer and the bit line and between the recordable layer and the word line.

### 5. Fabrication of the Memory Device

A variety of manufacturing approaches can be used to fabricate the thin sub-layers of the recordable layer 110. For example, each layer can be formed on top of the previous layer by physical vapor deposition (PVD), chemical vapor deposition (CVD), plasma enhanced chemical vapor deposition (PECVD), metal organic chemical vapor deposition (MOCVD), or molecular beam epitaxy (MBE).

The thin film memory device 100 can be fabricated using standard CMOS (complementary metal oxide semiconductor) processes. Because of the simple structure of the thin film memory device 100, the memory device 100 can be fabricated using a 1-metal, 1-poly process. By comparison, a conventional Flash memory device is typically fabricated using a 3-metal, 4-poly process, or more complex processes.

### 6. Formation and Combination of Thin Layers

### 6.1 Continuous Layers of Materials

Each of the two thin layers 204 and 206 of the memory device 200 (FIG. 7A) can be a continuous layer of material, which can be formed by using techniques that include, without limitation, physical vapor deposition, chemical vapor deposition, plasma enhanced chemical vapor deposition, metal organic chemical vapor deposition, or molecular beam epitaxy.

### 6.2 “Islands” of Materials

As described above, a thin layer of material can be formed in a spatially continuous manner. This continuous film can be deposited on top of a previously deposited layer, and controlling the deposit rate and deposition time so that a desired thickness is achieved. Note that the Debye length of materials (for example, metals) having a high carrier density can be less than one nanometer at room temperature. As an alternative to the potentially difficult process of depositing a layer of material having such a small thickness, discontinuous regions or islands of materials can be deposited to achieve a desired “effective thickness,” which is defined as the volume of the material divided by the sum of the area covered by the material and the area in between the material. The diameters of the islands can be made smaller than the width of the word and bit lines 140 and 130. For example, when 130 nm semiconductor fabrication process is used, the width of the word and bit lines can be 130 nm, and the diameter of the islands can be made to be about 10 nm. Because each word line and bit line covers several islands of material, the islands appear to the word and bit lines as a continuous layer having the effective thickness. Such islands of material is used in the middle layer 308 of the memory device 300 (FIG. 8A).

Islands of materials can be formed by using techniques that can include, without limitation, physical vapor deposition, chemical vapor deposition, plasma enhanced chemical vapor deposition, metal organic chemical vapor deposition, or molecular beam epitaxy described above, but with a lower operating power, or with a shorter operating duration.

In some examples, the islands may have different sizes, and some islands may be connected. In some examples, as the material that is deposited increases, many of the islands become connected, resulting in a continuous layer of material having spaces (or holes) distributed across the layer, such that the layer of material does not completely cover or overlap the other layers.

In some examples, a layer of islands of material M2 is formed on top of a spatially continuous layer of material M1. Suppose the average thickness of the islands of material M2 is 5 nm, and the islands cover or overlap about 15% of the layer of material M1, then the effective thickness of the material M2 would be approximately 5 nm×15%=0.75 nm.

In some examples, a spatially continuous layer of material M2 is deposited on top of islands of material M1. In some examples, islands of materials M1 and M2 are deposited on a lower layer. In some examples, islands of stacks of materials M1 and M2 are formed by, for example, depositing continuous layers of materials M1 and M2, then etching the continuous layers to form the stacks.

Structures that include one or more layers of islands of material are useful in constructing memory cells that are resistive before inscription and become diode-like after inscription.

### 6.3 Using a Chemical Reaction to Form a Thin Layer

Another way to form a thin layer is to induce a chemical reaction with a material. For example, the layer 204 in FIG. 7A can be formed by oxidizing the layer 206. Note that an electric field that is generated due to charge separation, described in Section 3.3 above, can either help or prevent a chemical reaction (including oxidization) from occurring, depending on the direction of the electric field. In one example, the layer 206 is a layer of silicon. By passing air (which includes oxygen and nitrogen) over the layer of silicon, a thin layer of silicon oxide is formed on the layer of silicon. The silicon oxide can grow on either side or both sides of the silicon layer. In another example, nitrogen interacts with the material in the layer 206 to form a nitride, which becomes the layer 204.

### 6.4 Combining the Thin Layers

As discussed above, when two layers are thin (for example, less than the effective Debye lengths), the combination of the two layers can be facilitated by the electric field generated by charge separation. A smaller amount of energy per unit volume or per unit area may be required to form the combination, as compared to the energy required to cause two thicker layers to combine. Combination of two thin layers can be achieved by, in various versions of the system, for example, without limitation, mixing, boundary blurring, alloying, chemical reaction, diffusion, or field induced mass transfer over boundary. The reaction between the two layers can be endothermic or exothermic.

### 7. Examples of Recordable Layers

Samples of electrical thin film memory devices were prepared and their electrical properties before and after thermal treatment (or inscription) were measured. Each electrical thin film memory included a recordable layer having a thin semiconductor layer sandwiched between two thin metal layers. In each of these samples, the recordable layer has a diode-like characteristic before inscription and a resistor-like characteristic after inscription.

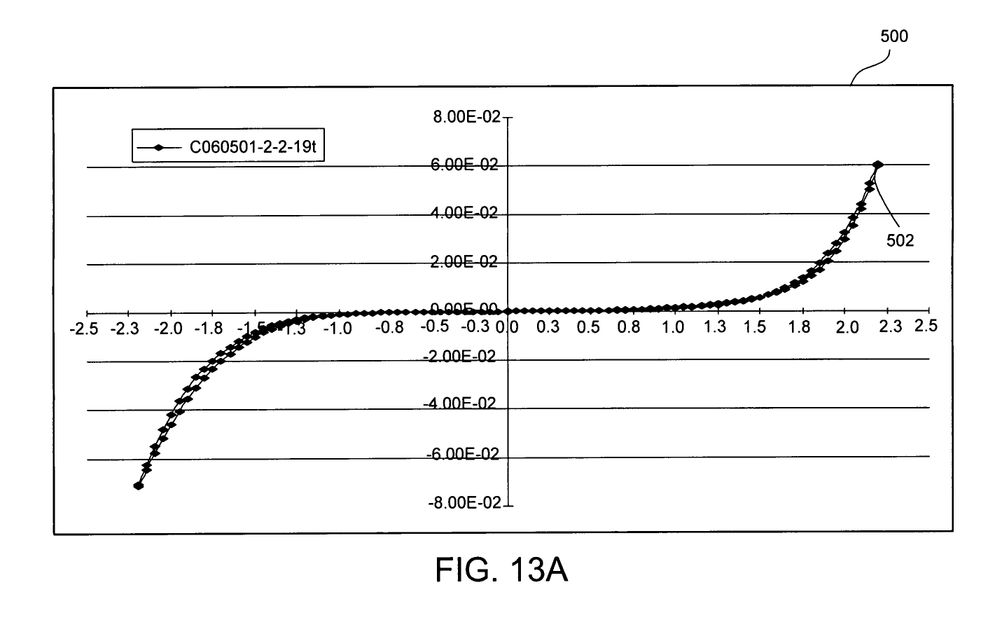

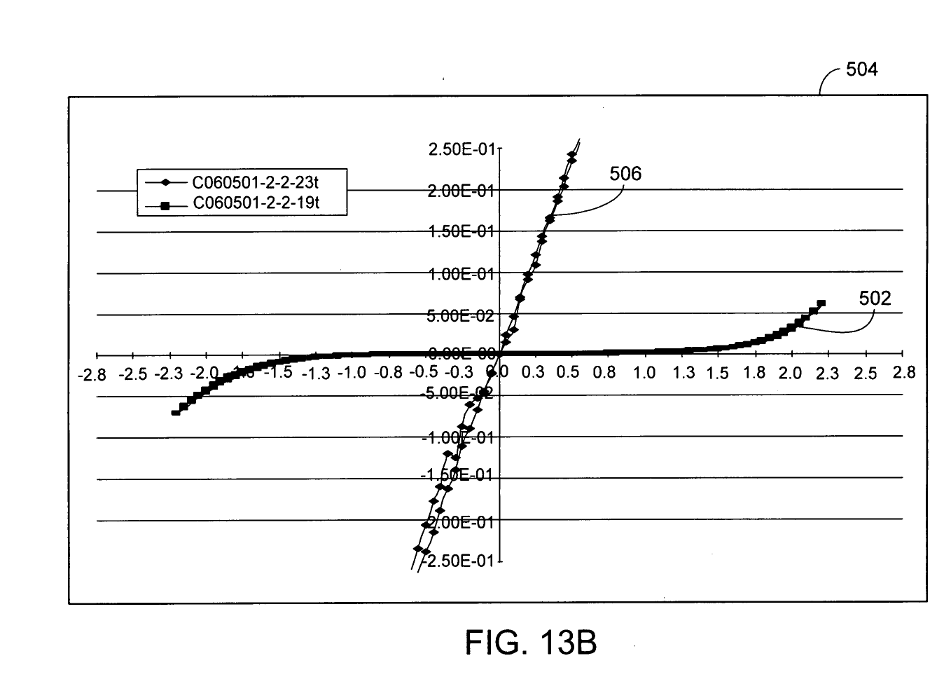

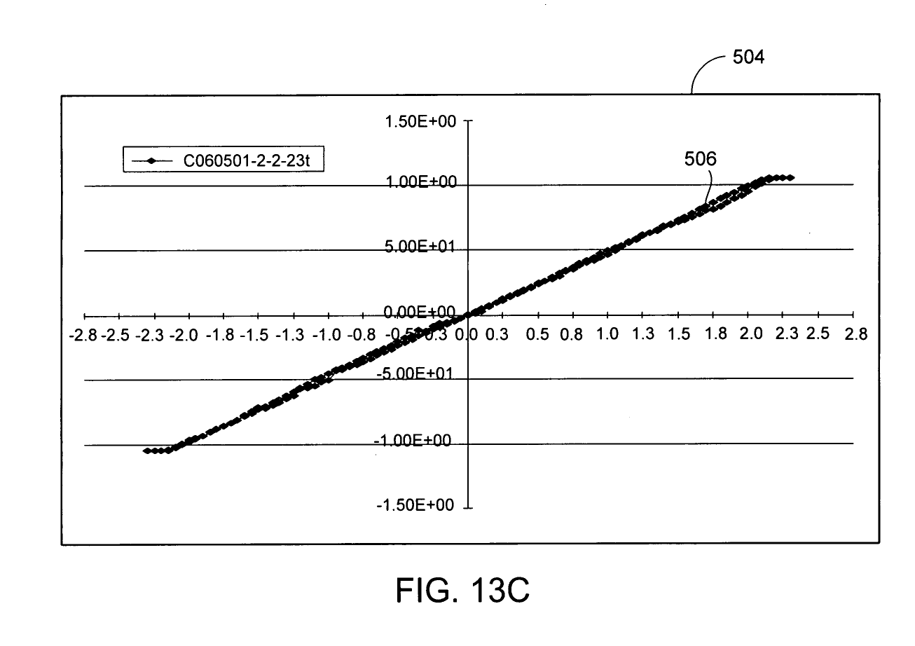

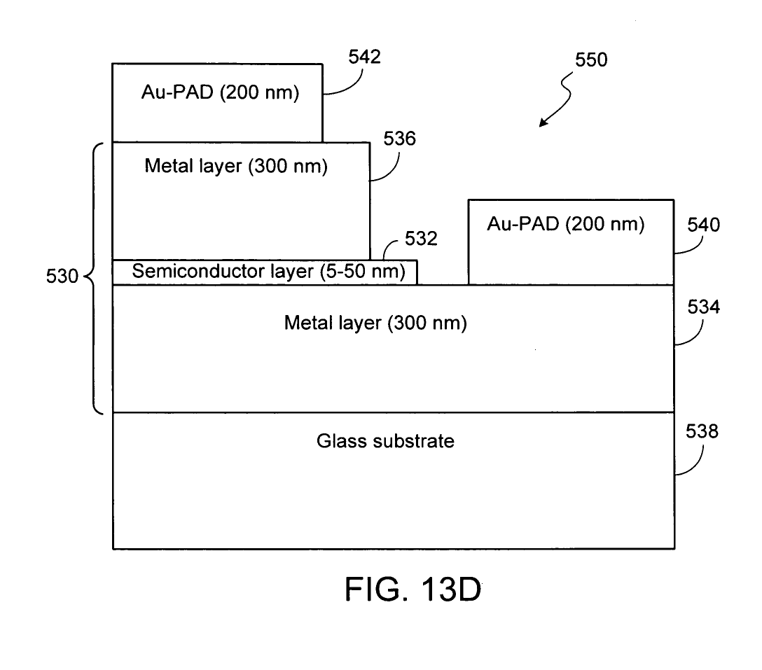

FIG. 13D is a schematic diagram representing the electrical thin film memory devices 550 that were prepared. The electrical thin film memory 550 includes a recordable layer 530, which has a layer of semiconductor 532 that is sandwiched between two layers of metal 534 and 536. The metal and semiconductor thin films were deposited on a glass substrate 538. Gold contacts 540 and 542 were deposited on the metal layers 534 and 536, respectively, to provide sufficiently large probe areas and to provide good ohmic contacts between metal layer and probes used to measure the electrical characteristics of the recordable layer 530.

A number of samples were prepared, in which the thicknesses of the semiconductor layers 532 ranged from about 7 nm to about 15 nm. The semiconductor layers 532 were made of silicon or germanium doped with boron or phosphorus. The metal layers 534 and 536 were made of aluminum, and each had a thickness of about 300 nm.

Each of the thin film memory 530 was fabricated using the following process. Prior to depositing the thin films, the glass substrate 538 was cleaned by using a ultrasonic cleaner and was soaked in acetone or ethanol for at least 10 minutes. A Modular Single Disk Sputtering System “Trio CUBE” (Balzers) equipped with two DC cathodes and one RF cathode, available from Unaxis, was used to deposit the layers. The base pressures of the main chamber and the process chamber were maintained below 10⁻⁷ mbar. The operation pressure in the process chamber was set to be in the range of 10⁻³ to 10⁻² mbar during film deposition. When depositing the layers, the thicknesses of the layers were controlled by controlling the sputtering time The thickness of each of the thin layers was measured and estimated based on the sputtering yield of the material, the sputtering time (typically from 1 to 20 seconds), and the sputtering power density (typically 4 to 15 W/cm²) used for the layer.

Each of the samples has an overall dimension of 32×24 mm². The area between the two metal layers 540 and 542 is about 88 mm².

FIGS. 13A-13C show experimental data for one of the samples of the electrical thin film memory 530 (FIG. 13D). The data shows that the thin film memory 530 has a diode-like current-voltage characteristics before inscription, and a resistor-like current-voltage characteristics after inscription.

FIG. 13A is a graph 500 that shows a curve 502 representing the current-voltage characteristics of the thin film memory 530 before inscription. When the voltage across the thin film memory is between −1V to 1V, the current flowing through the thin film memory 550 is very small. Even when the increases to 1.8V, the current is still less than 20 mA. When the voltage is greater than 2.3 V, the current increases significantly. This is similar to the current-voltage characteristics of a diode having a breakdown voltage of about 2.3V.

FIG. 13B is a graph 504 that shows a curve 506 that represents the current-voltage characteristics of the electrical thin film memory 550 after inscription. As can be seen from the curve 506, after inscription, the current flowing through the thin film memory 550 increases substantially proportional to the voltage, indicating that the thin film memory 550 behaves like a resistor.

FIG. 13C shows the graph 504 with the vertical scale compressed to show that the thin film memory 550 behaves like a resistor after inscription for voltages ranging from 0 to 2.1 V.

Comparing the curves 502 and 506, when a read pulse is applied to the thin film memory 550, the current flowing through the thin film memory 550 before inscription is much smaller than after inscription. In some examples, an un-inscribed memory cell represents a logic ‘0’, and an inscribed memory cell represents a logic ‘1’. Thus, information can be recorded in the memory cells by inscribing selected ones of memory cells. Afterwards, the information stored in the thin film memory 550 can be detected by applying read pulses to the memory cells and detecting whether the response current is less than a predetermined threshold (which represents a logic ‘0’) or greater than the predetermined threshold (which represents a logic ‘1’).

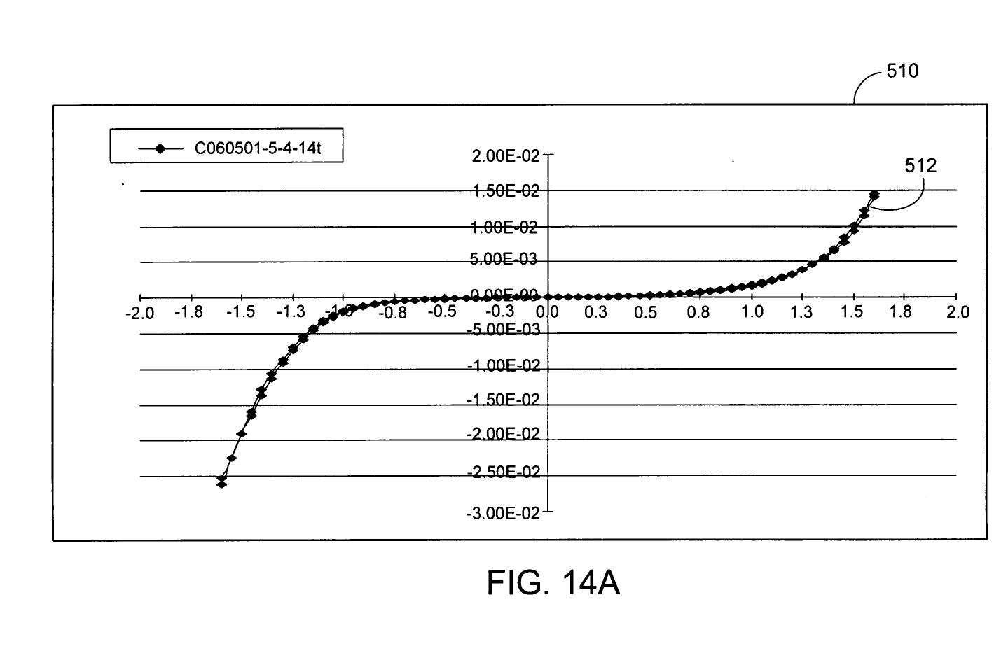

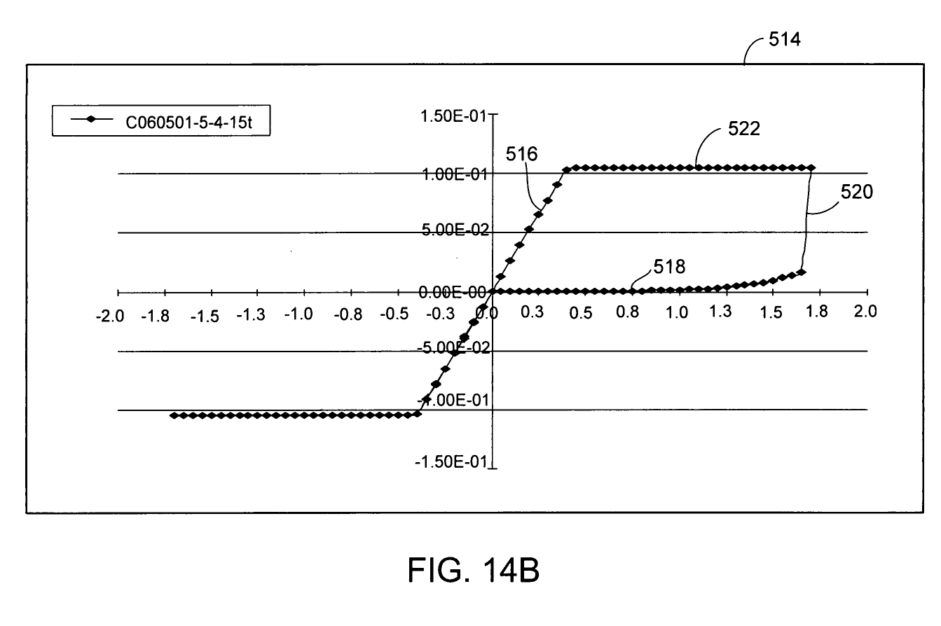

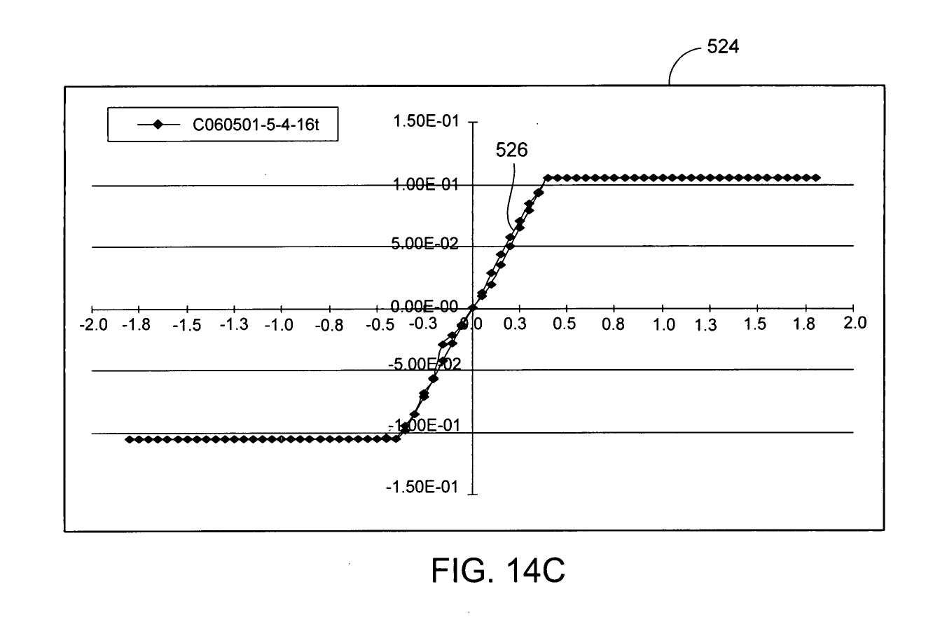

FIGS. 14A-14C show experimental data for another one of the samples of the electrical thin film memory 530 (FIG. 13D). The data shows that the electrical thin film memory 550 has a diode-like current-voltage characteristics before inscription, and a resistor-like current-voltage characteristics after inscription.

FIG. 14A is a graph 510 that shows a curve 512 representing the current-voltage characteristics of the thin film memory 550 before inscription. When the voltage across the thin film memory 550 is between −0.5 V to 0.5 V, the current flowing through the thin film memory 550 is less than 2 mA. Even when the increases to 1.4V, the current is still less than 5 mA. When the voltage is greater than 1.7 V, the current increases significantly. This is similar to the current-voltage characteristics of a diode having a breakdown voltage of about 1.7V.

FIG. 14B is a graph 514 that shows curves that represent a transition from a diode-like characteristic to a resistor-like characteristic. A curve 518 indicates that when the voltage applied to an un-inscribed memory cell is increased from 0V to about 1.7 V, the current increases from 0 to about 15 mA. A curve 520 indicates that when the voltage increases above 1.7 V, the current abruptly increases to about 105 mA. This shows that the semiconductor layer 532 and metal layers 540 and 542 combine to change the physical and electrical characteristics of the thin film memory 550 when a write pulse of 1.7V is applied. A curve 522 indicates that when the voltage decreases from 1.7V to about 0.4 V, the current remains substantially constant at 105 mA. A curve 516 indicates that when the voltage decrease from about 0.4 V to −0.4 V, the current decreases linearly with respect to the voltage.

FIG. 14C is a graph 524 that shows a curve 526 representing the current-voltage characteristic of the thin film memory 550 after inscription. When a read voltage between −0.4 to 0.4 V is applied to the thin film memory, the current varies substantially linearly with respect to the voltage. Thus, the thin film memory behaves like a resistor for voltages ranging from −0.4 V to 0.4 V.

Comparing the curves 526 and 512 (FIG. 14A), when a read pulse is applied to the thin film memory, the current flowing through the thin film memory before inscription is much smaller than after inscription. Thus, information recorded in the memory cells of the thin film memory 550 can be detected by applying read pulses to the memory cells and comparing the detected current with a threshold value.

### 8. Alternative Recording Structures

In the examples above, generally, a thin film memory device has one recordable layer that includes one or more thin sub-layers. Alternatively, a thin film memory device can also have two or more recordable layers, each including one or more thin sub-layers. The additional recordable layers allow the memory device to have a larger storage capacity.

### 8.1 Multiple Recordable Layers

Approaches of the types described above can be applied to write-once recording media that uses two or more inscription layers to increase the density of memory cells.

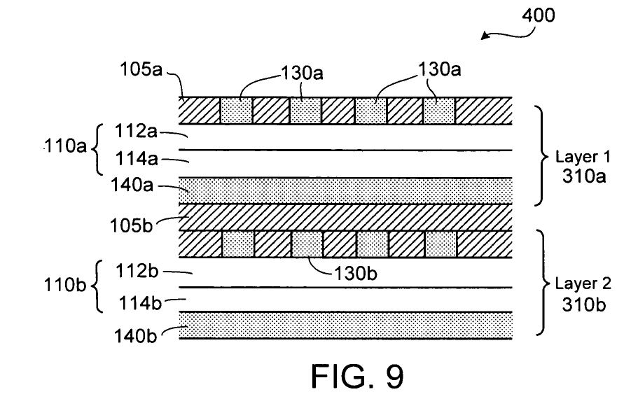

FIG. 9 shows a schematic diagram of a cross section of a dual-layer thin film memory device 400 that includes a first layer 310a and a second layer 310b. The first layer 310a includes word lines 140a, a recordable layer 10a, and bit lines 130a. The recordable layer 110a includes a first sub-layer 112a and a second sub-layer 114a. A layer of insulating material 105a fills the space between bit lines 130a.

Similar to the first layer 310a, the second layer 310b includes word lines 140b, a recordable layer 110b, and bit lines 130b. The recordable layer 110b includes a first sub-layer 112b and a second sub-layer 114b. A layer of insulating material 105b fills the space between bit lines 130a, and also serves as a buffer between the first and second layers 310 and 310b.

As an alternative, if the memory cells in the first layer 310a can be accessed simultaneously with the memory cells in the second layer 310b, then the word line 140a of the first layer 310a and the bit line 130b of the second layer 310b can be combined.

Each of the first layer 310a and the second layer 310b operates in a manner similar to the memory device 300, in which after application of a write pulse, the memory cell changes from diode-like to resistor-like, the resistance of the recordable layer changes, the capacitance of the recordable layer changes, or the recordable layer switches between being resistive and capacitive.

Similar to the process for manufacturing the memory device 100 of FIG. 5, a variety of manufacturing approaches can be used to fabricate the thin sub-layers of the recordable layers of the memory device 400. For example, each layer can be formed on top of the previous layer by physical vapor deposition (PVD), chemical vapor deposition (CVD), plasma enhanced chemical vapor deposition (PECVD), metal organic chemical vapor deposition (MOCVD), or molecular beam epitaxy (MBE).

### 9. System Architecture

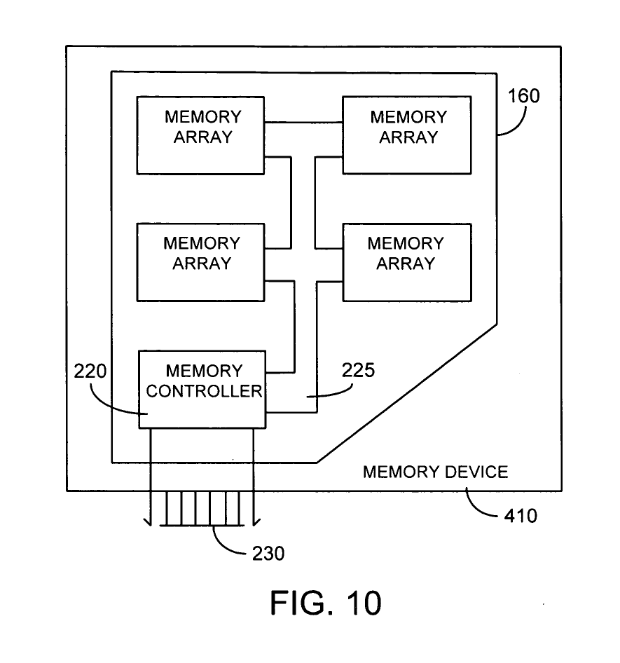

FIG. 10 is a block diagram of a memory device 410 that includes the chip 160, which has a memory controller 220 and multiple memory arrays 210. Each of the memory arrays 210 can be similar to the memory device 100, 200, 300, or 400 (see FIG. 5, 7A, 8A, or 9). The memory controller 220 controls the memory arrays 210 through buses 225. The memory controller 220 also interacts with a host device (not shown), such as a computer or a digital camera, through an interface 230. The memory device 410 may comply with interface standards such as Universal Serial Bus or IEEE 1394 (Firewire) standards. The memory device 410 can be made into a memory card, and partially comply with, for example, the coding/decoding schemes of Compact Flash, Secure Digital, Memory Stick, or XD Memory Card standards. The memory device 410 is a write-once device rather than a re-writable device. The memory device 410 does not necessarily have to comply with the read/write voltages of the standards listed above.

The memory controller 220 may operate in a manner compatible with existing flash memory devices. In some examples, the memory controller 220 is compatible with NOR flash architecture, and writes data to the memory arrays 210 one byte or word at a time. In some examples, the memory controller 220 is compatible with NAND flash architecture, which read/write the data sequentially in a predefined length of memory strings, but can randomly access which string to be read from or written to.

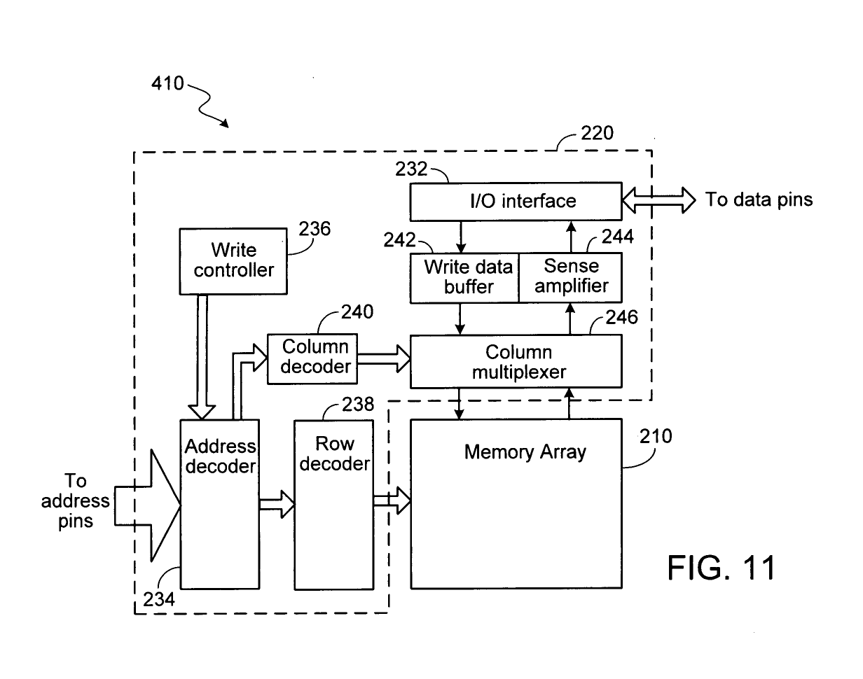

Referring to FIG. 11, the memory controller 220 includes an input/output interface 232 that receives commands and writes data from, and outputs read data to, data pins. The commands are sent to a write controller 236 that controls how data are written to or read from the memory array 210. The write controller 236 controls an address decoder 234 that receives addresses of the memory cells to be accessed from address pins. The address decoder 234 sends row and column information to a row decoder 238 and a column decoder 240, respectively, which determine which word line and bit line to activate to access specific memory cells. A write data buffer stores data to be written to the memory array 210. A sense amplifier 244 amplifies the signals (read data) read from the memory array 210. A column multiplexer 246 multiplexes the write data and the read data on the bit lines of the memory array 210.

For example, upon receiving a write command, the memory controller 220 may send a write pulse having a voltage level of, for example, 1 volt, to specified memory cells to write data in the cells. Upon receiving a read command, the memory controller 220 may send a read pulse having a voltage level of, for example, 10 to 500 mV, to specified memory cells to read data from the cells.

In some examples, the memory controller 220 can translate between virtual memory addresses and physical memory addresses. The host device sends virtual memory addresses to the memory controller 220. The memory controller 220 translates the virtual addresses to physical addresses and accesses memory cells according to the physical addresses. The memory device 410 may be tested at the factory for defects, and the addresses of defective cells can be stored in a table. When the host device writes to the memory device 410, the memory controller 220 skips the defective cells and only writes to functional memory cells.

For example, when the host controller sends an erase command to erase data at certain virtual addresses, the memory controller 220 may mark corresponding physical addresses as being “erased,” so that the data at those physical addresses cannot be retrieved. When the host device sends a write command to write to a virtual address that has previously been erased, the memory controller 220 translates the virtual address to a different physical address and writes to the new physical address. In this way, even though the memory cells are write-once only and cannot be physically erased, the memory device 410 will appear to the host device as if the memory cells can be erased for a limited number of times.

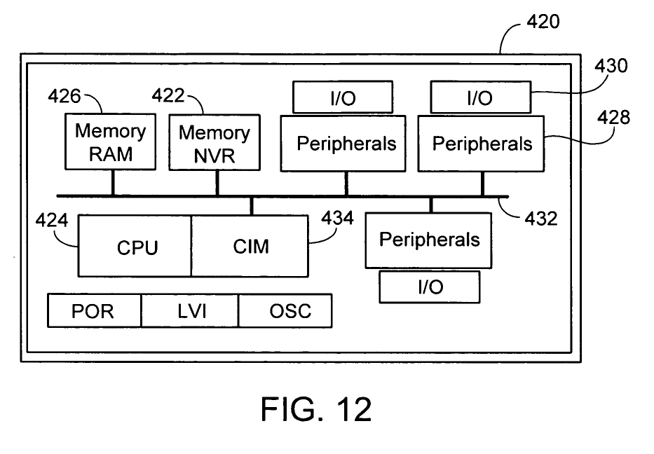

Referring to FIG. 12, the electrical thin film memory device 100 can be used as a non-volatile memory 422 of a micro-controller unit 420. The micro-controller unit 420 also includes a central processing unit 424 and a random access memory (RAM) 426. The non-volatile memory 422 allows the user to customize programs (e.g., obtaining a most recent version of firmware) before permanently writing the programs into the memory 422. During run time, the programs are loaded from the non-volatile memory 422 and stored in the RAM 426 to allow faster access of the program code. The micro-controller unit 420 includes peripheral modules 428 for processing signals from input/output ports 430. The device includes a chip integration module (CIM) 434 and supporting modules POR, LVI, and OSC. The various modules communicate with one another through a bus 432.

Although each memory cell of the non-volatile memory 422 can be programmed only once, the non-volatile memory 422 can be made to have a capacity several times larger than the amount required for storing one version of the firmware. When the firmware needs to be upgraded, the new version of the firmware is written to a different portion of the non-volatile memory 422. This way, the non-volatile memory 422 can be programmed a finite number of times to store multiple versions of the firmware, each time writing to a different portion of the memory 422.

### 10. Additional Alternative Examples

The various layers of the recordable layers 110, 202, 302 can have materials and thicknesses other than those described above. The recordable layers can be made using methods other than those described above.

In FIG. 5, rather than covering the entire chip area with the recordable layer 110, an additional photo mask can be used to pattern the recordable layer 110 so that the layer 110 only covers the WOEM area 162, or portions of the WOEM area 162.

In FIG. 9, each of the first layer 310a and the second layer 310b can have a single layer (such as in FIG. 1A) or multiple layers, and can include one or more layers of islands of materials (such as in FIG. 8A). The first layer 310a and the second layer 310b may have different structures. For example, the first layer 310a may have a single layer of material, and the second layer 310b may have two or more layers of materials. The memory device 400 can include three or more layers that are similar to layers 310a and 310b.

The memory device can be a memory card having interface and/or physical dimensions that comply with various storage standards, such as flash memory standards. The memory device can also have an arbitrary shape. The memory device does not necessarily have to be flat, and can, for example, conform to the surface contour of a cube, a ball, or any other arbitrary volume.

The memory controller can have different configurations so that the processes for writing and reading data are different that those described above. The electrical thin film memory device can be integrated into systems other than those described above.

The electrical thin film memory device can be written using, for example, magnetic or optical methods, and read electronically. For example, instead of applying electrical pulses to selected memory cells to write marks in the cells, a light beam may be used to apply energy to selected memory cells to write the marks. After the marks have been written, an electric read pulse is applied to memory cells to detect contrast in electrical properties, such as resistance and/or capacitance, to read information stored in the memory cells.

In the example of FIG. 13A, only positive read and write voltages are used. In other example, negative read and write voltages can also be used.

It is to be understood that the foregoing description is intended to illustrate and not to limit the scope of the invention, which is defined by the scope of the appended claims. Other embodiments are within the scope of the following claims.

What is claimed is:

1. A memory device comprising:
a layer of material;
a plurality of memory cells each formed using a corresponding different portion of the layer, wherein each memory cell is constructed and designed to change a material property of the corresponding portion of the layer upon application of an electrical write signal; and
circuitry for outputting a signal indicating presence or absence of a change of the material property in the memory cells.

2. The memory device of claim 1 in which, for each of at least some of the memory cells, prior to application of the write pulse, a Schottky barrier forms at an interface between the layer of material and a metal electrode or a metal layer, and after inscription, the interface becomes an ohmic junction.

3. The memory device of claim 1 in which, for each of at least some of the memory cells, the memory cell has a diode-like current-voltage characteristic before inscription, and has a resistor-like current-voltage characteristic after inscription.

4. The memory device of claim 1 in which, for each of at least some of the memory cells, the memory cell has a resistor-like current-voltage characteristic before inscription, and has a diode-like current-voltage characteristic after inscription.

5. The memory device of claim 1 in which, for each of the memory cells, the change in the material property of the layer is associated with a change in an electrical property of the layer.

6. The memory device of claim 5 in which the electrical property includes a resistivity of the layer.

7. The memory device of claim 6 in which the resistivity decreases after application of the write signal.

8. The memory device of claim 6 in which the resistivity increases after application of the write signal.

9. The memory device of claim 5 in which the electrical property includes presence of a Schottky barrier.

10. The memory device of claim 5 in which the electrical property includes a dielectric constant of the layer.

11. The memory device of claim 10 in which the dielectric constant decreases after application of the write signal.

12. The memory device of claim 5 in which the dielectric constant increases after application of the write signal.

13. The memory device of claim 1, further comprising electrodes for transmitting the write signal.

14. The memory device of claim 13 in which at least one of the memory cells comprises a layer that combines with a portion of the electrodes upon application of the write signal.

15. The memory device of claim 1 in which at least one of the memory cells comprises a first layer and a second layer that combine upon application of the write signal.

16. The memory device of claim 1 in which the write signal comprises a voltage pulse.

17. The memory device of claim 1, further comprising electrodes for sending the read and write signals to each memory cell, in which the electrodes do not interact with the layer of material upon application of the write signal to the memory cells.

18. A memory device comprising:
a plurality of memory cells, each memory cell constructed and designed to change a material property of a layer of material associated with the memory cell upon application of a write signal;
word lines and bit lines to select one or more memory cells;
a controller to apply write signals to at least some of memory cells to change the material property of the layer of material associated with the at least some of the memory cells, and to apply read signals to at least some of memory cells to detect the material property at the at least some memory cells.

19. A memory device comprising:
a recording layer including a recordable stack of one or more material layers, at least one of the material layers having a thickness less than 50 nm, the recordable stack having a top surface and a bottom surface; and
circuitry disposed on the top and the bottom surfaces of the recordable stack;
wherein the circuitry is configured to, at any of a plurality of selectable locations on the recordable stack, (a) apply an electrical signal across the stack at the selected location causing a change of a material property at that location, and/or (b) sense the material property of the recordable stack at that location.

20. The memory device of claim 19 wherein the circuitry comprises a plurality of electrical conductors disposed on top and bottom surfaces of the recordable stack intersecting at the selectable locations.

21. The memory device of claim 19 wherein at least one of the material layers is less than 25 nm thick.

22. The memory device of claim 21 wherein at least one of the material layers is less than 10 nm thick.

23. The memory device of claim 19 wherein at least one of the material layers is less three times a Debye length of the material in that layer.

24. The memory device of claim 19 wherein the stack of material layers includes a first layer and a second adjacent layer, the materials of the first and second layers being selected from a group consisting of: semiconductor/semiconductor, semiconductor/metal, semiconductor/metal oxide, and non-metal/metal.

25. The memory device of claim 19 wherein the electrical signal causes at least one of a chemical reaction between the layers, mixing of the layers, and diffusion of material between the layers, at that location.

26. The memory device of claim 25 wherein the electrical signal causes an endothermic chemical reaction between the layers.

27. The memory device of claim 19 wherein the memory device is non-volatile.

28. The memory device of claim 19 wherein the memory device is a write-once device.

29. A memory device comprising:
a recordable layer;
a first electrode, the recordable layer and the first electrode comprising materials selected such that a Schottky barrier forms at an interface between the recordable layer and the first electrode before inscription, and after inscription, the interface becomes an ohmic junction; and
a second electrode, a write signal being applied to the recordable layer through the first and second electrodes during inscription.

30. The memory device of claim 29 in which the recordable layer and the second electrode comprise materials selected such that a Schottky barrier forms at an interface between the recordable layer and the second electrode before inscription, and after inscription, the interface becomes an ohmic junction.

31. A method of accessing a memory device that comprises a recordable layer and a plurality of memory cells each formed using a corresponding different portion of the recordable layer, the method comprising:
applying a write pulse to a memory cell to change a material property of the corresponding portion of the recordable layer of the memory cell to generate a contrast in the material property between the memory cell that has been applied the write pulse and other memory cells that have not been applied write pulses.

32. The method of claim 31, further comprising applying a read pulse to a memory cell to probe the material property of the recordable layer of the memory cell, and reading a read signal representative of the material property at the memory cell.

33. The method of claim 31, wherein changing a material property of the corresponding portion of the recordable layer comprises changing the current-voltage characteristics of the recordable layer from diode-like characteristics before inscription to resistor-like characteristics after inscription.

34. The method of claim 31, wherein changing a material property of the corresponding portion of the recordable layer comprises changing a resistivity of the recordable layer.

35. The method of claim 31, wherein changing a material property of the corresponding portion of the recordable layer comprises changing a dielectric constant of the recordable layer.

36. The method of claim 31 wherein changing a material property of the corresponding portion of the recordable layer comprises causing at least one of a chemical reaction between the sub-layers of the recordable layer, mixing of the sub-layers, and diffusion of material between the sub-layers.

37. The method of claim 31 wherein changing a material property of the corresponding portion of the recordable layer comprises causing an endothermic chemical reaction between sub-layers of the recordable layer.

38. The method of claim 31 wherein applying a write pulse comprises applying a voltage pulse.

39. A method comprising:
fabricating a recordable layer;
fabricating a plurality of memory cells each formed using a corresponding different portion of the recordable layer, wherein each memory cell is constructed and designed to change a material property of the corresponding portion of the recordable layer upon application of an electrical write signal;
fabricating write circuitry for applying write signals to the memory cells; and
fabricating read circuitry for outputting signals from the memory cells providing information about the material property of the recordable layer in the memory cells.

40. The method of claim 39 wherein fabricating the recordable layer comprises depositing two or more layers of materials on a substrate, in which at least one of the layers has a thickness less than 50 nm.

41. The method of claim 39 wherein depositing two or more layers of materials comprises depositing a layer of islands of material.

42. The method of claim 39 wherein depositing two or more layers of materials comprises depositing materials that interact in an endothermic reaction upon application of a write signal.

43. The method of claim 39 wherein fabricating the plurality of memory cells comprises using a 1-poly, 2-metal semiconductor process to fabricate the memory cells.
